(19) United States
(12) Patent Application Publication
(10) Pub. No.: US 2023/0300971 A1
(43) Pub. Date: Sep. 21, 2023

(54) POWER CONTROLLER

(71) Applicant: MGM COMPRO S.R.O, Zlin (CZ)

(72) Inventor: Grigorij DVORSKÝ, Zlin (CZ)

(21) Appl. No.: 18/021,589

(22) PCT Filed: Aug. 17, 2021
(86) PCT No.: PCT/CZ2021/050088

§ 371 Date: Feb. 16, 2023

(30) Foreign Application Priority Data
Aug. 17, 2020 (CZ) PUV 2020-37886

(51) Int. Cl. H05K 1/02

(52) U.S. Cl. CPC H05K 1/0206; H05K 2201/066

(57) ABSTRACT

Power controller for electric power flow control, consisting of at least one printed circuit board for supporting and electrically interconnecting power controller components. Power controller further consists of at least one power switching element (21) arranged on one the side of the printed circuit board, and at least one heat sink (28) arranged on the remaining side of the printed circuit board. The printed circuit board is provided with a network of openings (29) passing through the printed circuit board, with the openings (29) being plated or completely filled with metal. At the same time, there is at least one layer (27) of thermally conductive and electrically insulating material between the heat sink (28) and the printed circuit board.

### FIELD OF THE INVENTION

The present invention relates to an electric power flow controller, which serves in particular for controlling the operation of an AC or DC electric motor.

### BACKGROUND OF THE INVENTION

When connected to the power supply, the electric motor starts up at some speed. However, many applications of electric motors require that the electric motors have variable speed. For this purpose, power controllers have begun to be used, which can change the power supply parameters of the electric motor in a controlled manner, thus essentially controlling the operation of the electric motor. Known types of electric motors according to the design include, for example, BLDC electric motors or PMSM electric motors, etc.

Controllers fall into the category of so-called power electronics, which is nowadays a very intensively developing technical field, which is focused on the effective control of the flow of electric power, which is used to supply a wide range of appliances. The task of power applications falling into this technical field is the conversion, control and modification of electric power, the conversion being a change of at least one characteristic quantity of the power system by means of electronic switching components without significantly higher power loss.

Power controllers can be generally described by technical features, including a printed circuit board that provides support for electronic components, as well as electronic components designed to meet the goal of power application, and last but not least, electrically conductive printed circuit boards, which serve as electric power interconnections between electronic components. An example of a power controller can be, for example, the invention in invention application PV 2003-333 A.

A known shortcoming of controllers operating with large flows of electric power involves the problem of waste heat. As the flow of electric power passes through the printed circuit boards and electronic components across the printed circuit board, it must overcome their ohmic electric resistance. Another known disadvantage is the presence of parasitic inductance between adjacent electric elements on the printed circuit board (so-called inductance of PCB conductive paths).

The task of the invention is to provide a power controller, the construction of which would enable efficient removal of waste heat of power components and at the same time supply/discharge high flows to/from power components.

### SUMMARY OF THE INVENTION

The set task is solved by means of an electric power flow controller created according to the invention below.

The power controller for electric power flow control consists of at least one printed circuit board for supporting and electrically interconnecting the components of the power controller. Another component of the power controller is at least one power switching element arranged on one of the sides of the printed circuit board. Furthermore, the power controller consists of at least one heat sink arranged on the remaining side of the printed circuit board.

The summary of the invention is based on the fact that the printed circuit board is provided with a network of openings under the power component(s) passing through the printed circuit board, with the openings being plated or completely filled with metal, and at the same time, there is at least one layer of thermally conductive and electrically insulating material between the heat sink and the printed circuit board.

This is advantageous from the point of view of the efficiency of heat removal from the power element. Plated or metal-filled openings act as thermal bridges, through which heat is conducted to the heat sink more easily than if it had to radiate through the material of the printed circuit board.

The diameter of openings is preferably of the order of 0.2 to 0.25 mm and the spacing of adjacent openings is of the order of 0.1 mm to 0.5 mm Thanks to the appropriately selected size of openings and their spacing it is possible to create a dense network of openings. In addition, it is advantageous if the thickness of plating of the opening is in the range from 20 μm to 60 μm, or if they are completely filled with metal.

In another preferred embodiment of the power controller according to the invention, the plate electrode of the housing of the power switching element is in contact with plating, or with a metal filling of at least one of the openings. In this way, the openings also fulfil the second function, which is the distribution of electric current.

The advantages of the controller include better removal of waste heat to the heat sink and the resulting ability to process higher electric power. Another advantage is that the openings can serve to distribute electric current, thus making it possible to supply the components on the printed circuit board from below.

### EXPLANATION OF DRAWINGS

The present invention will be explained in detail by means of the following figures where:

FIG. 1 schematically shows a section of a controller through its power switching element, a printed circuit board and a heat sink,

FIG. 2 schematically shows a network of openings through a printed circuit board.

### EXAMPLE OF THE INVENTION EMBODIMENTS

It shall be understood that the specific cases of the invention embodiments described and depicted below are provided for illustration only and do not limit the invention to the examples provided here. Those skilled in the art will find or, based on routine experiment, will be able to provide a greater or lesser number of equivalents to the specific embodiments of the invention which are described here.

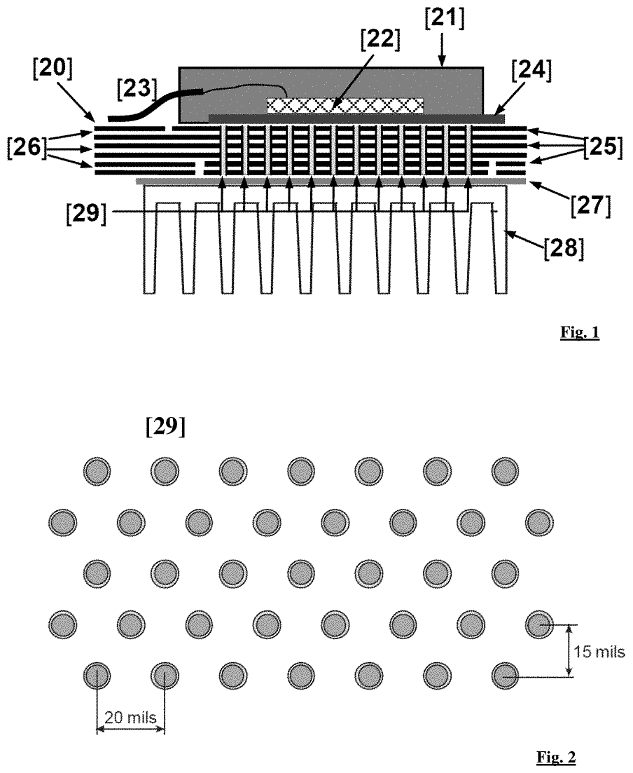

The schematic section of FIG. 1 shows an SMD power switching element 21 (MOSFET, SiC, etc.), which has on the one hand conventional outlets 23 (electrodes as S or G) connected to the chip 22, and on the other hand D electrode 24 oriented below the element 21 with the largest surface area. SMD stands for Surface Mount Device.

Through this electrode 24, the element 21 is firstly most cooled (i.e. removes heat generated by the passage of current through the element 21 and also generated by the switching of current (switching losses)), and secondly the current is thus supplied (removed) to the element 21. The element 21 is soldered with the electrode 24 (mounting surface of the element 21) to the upper Cu layer 25 of the printed circuit board.

The printed circuit board is formed by several layers 25 of copper (Cu), which are insulated from each other by means of insulating layers 26. On the printed circuit board, a network of micro openings 29 with a diameter of the order from 0.2 mm to 0.25 mm with small spacings (of the order of 0.5 mm) is placed under the electrode 24 so that up to 400 such openings 29 can be placed on an area of about 10×10 mm. An example of the grid of these openings 29 is shown in FIG. 2.

The actual size and spacing of the openings 29 depend on the printed circuit board manufacturing technology used, as well as the magnitude of current flowing through the openings 29, as well as the amount of heat to be removed by the openings 29 to the heat sink 28.

The openings 29 are optimally plated in a layer 20 to 60 μm thick, or optionally in a thicker layer, or are completely filled with Cu, thanks to which they efficiently transfer the heat generated by operation of the power element 21 to the heat sink 28 through the thermally conductive and electrically insulating layer 27. At the same time, electric current is supplied through these openings 29 or their surface or the entire volume of the opening 29, depending on the technology used, to the electrode 24 of the SMD power element 21. It is irrelevant whether the heat sink 28 is air, liquid, etc. The use of SMD power elements 21 and their connection to the printed circuit board by means of a network of micro openings 29 is advantageous both from the point of view of minimizing the resistance of copper paths of the printed circuit board and from the point of view of minimizing parasitic inductances of the circuit.

### INDUSTRIAL APPLICABILITY

The electric power flow controller according to the invention finds its application in the field of regulation of electrical appliances, in particular electric motors.

### LIST OF REFERENCE NUMERALS

21 power switching element
22 chip
23 conventional outlet
24 power element housing electrode
25 printed circuit layer
26 insulating layer of printed circuit board
27 thermally conductive and electrically insulating layer
28 heat sink
29 opening

1. Power controller for electric power flow control consisting of at least one printed circuit board for supporting and electrically interconnecting power controller components, further comprising at least one power switching element (21) arranged on one of the sides of the printed circuit board, and at least one heat sink (28) arranged on the remaining side of the printed circuit board, characterized in that the printed circuit board is provided with a network of openings (29) passing through the printed circuit board, with the openings (29) being plated or completely filled with metal and at the same time, there is at least one layer (27) of thermally conductive and electrically insulating material between the heat sink (28) and the printed circuit board.

2. Power controller according to claim 1, characterized in that the diameter of the openings (29) is of the order of 0.2 mm to 0.25 mm, and the spacing of adjacent openings (29) is of the order of 0.1 mm to 0.5 mm.

3. Power controller according to claim 1, characterized in that the thickness of plating of the opening (29) is in the range from 20 to 60 μm.

4. Power controller according to claim 1, characterized in that a plate electrode (24) of the housing of the power element (21) is arranged between the power switching element (21) and the printed circuit board, with the plate electrode (24) being in contact with plating, or with a metal filling of at least one of the openings (29).

5. Power controller according to claim 2, characterized in that the thickness of plating of the opening (29) is in the range from 20 to 60 μm.

6. Power controller according to claim 2, characterized in that a plate electrode (24) of the housing of the power element (21) is arranged between the power switching element (21) and the printed circuit board, with the plate electrode (24) being in contact with plating, or with a metal filling of at least one of the openings (29).

7. Power controller according to claim 3, characterized in that a plate electrode (24) of the housing of the power element (21) is arranged between the power switching element (21) and the printed circuit board, with the plate electrode (24) being in contact with plating, or with a metal filling of at least one of the openings (29).
